(19) United States
(12) Patent Application Publication
(10) Pub. No.: US 2009/0053622 A1
(43) Pub. Date: Feb. 26, 2009

(54) FINE MASK AND METHOD OF FORMING MASK PATTERN USING THE SAME

(76) Inventor: Jun-Seok Lee, Goyang-si (KR)

Correspondence Address: SHERR & VAUGHN, PLLC, 620 HERNDON PARKWAY, SUITE 200, HERNDON, VA, 20170, US

(21) Appl. No.: 12/189,166

(22) Filed: Aug. 10, 2008

(30) Foreign Application Priority Data
Aug. 20, 2007 (KR) 10-2007-0083536

(51) Int. Cl. G03F 1/00

(52) U.S. Cl. 430/5

(57) ABSTRACT

In a semiconductor technology, a fine mask for a semiconductor and a method of forming a mask pattern using the same are disclosed. In order to improve accuracy of line width resolution and optical resolution in forming a pattern of a semiconductor wafer, the fine mask includes a first mask, including a first mask original plate, a first light-blocking pad pattern formed on the first mask original plate, a first main pattern including a plurality of first light-transmitting regions formed on the first light-blocking pad pattern, and a first sub-pattern including a plurality of phase shift regions between the first light-transmitting regions and at an outermost portion of the first mask original plate. A second mask includes a second mask original plate, a second light-blocking pad pattern formed on the second mask original plate, a second main pattern including a plurality of second light-transmitting regions formed on the second light-blocking pad pattern, and a second sub-pattern including a plurality of phase shift regions between the second light-transmitting regions.

The present application claims priority under 35 U.S.C. 119 to Korean Patent Application No. 10-2007-0083536 (filed on Aug. 20, 2007), which is hereby incorporated by reference in its entirety.

### BACKGROUND

Recently, as mask designs have become more elaborate, the amount of light transmitted from the mask can be appropriately adjusted using photolithography technology. Also, a new photoresist, a scanner with a high numerical aperture lens, and modified mask technology have been developed in order to overcome various technical limitations of manufacturing apparatus. In particular, optical proximity correction (OPC) technology has been useful in overcoming technical limitations in optical exposure apparatus. Accordingly, it is possible to effectively overcome an optical distortion phenomenon using optical proximity correction to improve an ultra-fine pattern process.

An optical image exposed through a mask may be transferred to photoresist film to form a latent pattern image. The latent pattern image may be converted into an actual image through a developing process. However, as line width is miniaturized and complexity increases, it becomes more difficult to resolve the finer line widths in semiconductors. In particular, with design rules for 90 nm or less, lighting technology for resolving a fine pattern, resist performance, mask resolution and the like are important determinants of optical resolution.

FIG. 1A illustrates a related double exposure mask. FIG. 1B illustrates two masks for forming the mask of FIG. 1A. FIG. 1C illustrates a resist pattern formed by the two masks shown in FIG. 1B, including an optical image and an exposure contour image 4, which are generated using a simulation tool. As shown in FIGS. 1A to 1C, a double exposure mask formed using two masks is effective in improving resolution. However, it is difficult to overcome optical limits of patterning techniques in design rules for 90 nm or less.

FIG. 1A illustrates the two masks of FIG. 1B optically overlapping each other. First main patterns 1 and second main patterns 2 are alternately arranged without overlapping each other on a mask original plate 3. That is, when two masks overlap each other, each of the first main patterns 1 is positioned between the second main patterns 2, while each of the second main patterns 2 is positioned between the first main patterns 1.

FIG. 1B illustrates the mask original plate 3 including virtual patterns 20 of the second mask and the mask original plate 3 including virtual patterns 10 of the first mask. Accordingly, a region for forming the second main patterns 2 is defined on the mask original plate 3 with the first main patterns 1 by the virtual patterns 20 of the second mask. Further, a region for forming the first main patterns 1 is defined on the mask original plate 3 with the second main patterns 2 by the virtual patterns 10 of the first mask. That is, when two masks overlap each other, the virtual patterns 20 of the second mask represent positions for forming the second main patterns 2, and the virtual patterns 10 of the first mask represent positions for forming the first main patterns 1.

After the two masks of FIG. 1B are aligned in an exposure apparatus, an exposure process is performed. However, when the two masks of FIG. 1B are aligned and exposed in the exposure apparatus according to the related technology, as seen in the exposure contour image 4 of FIG. 1C, when the patterns formed by exposure are close to each other, line width resolution deteriorates as represented by a portion A.

### SUMMARY

Embodiments relate to a semiconductor technology, and more particularly to a fine mask for a semiconductor and a method of forming a mask pattern using the same. Embodiments relate to a fine mask and a method of forming a pattern capable of improving accuracy of fine line width resolution. Embodiments relate to a fine mask and a method of forming a pattern using the same capable of improving accuracy of line width resolution in forming a pattern of a semiconductor wafer, thereby increasing the optical resolution. Embodiments relate to a fine mask and a method of forming a pattern using the same capable of improving accuracy of line width resolution by adding a sub-pattern for compensating a main pattern to the mask to enhance the optical resolution.

Embodiments relate to a fine mask including a first mask, including a first mask original plate, a first light-blocking pad pattern formed on the first mask original plate, a first main pattern including a plurality of first light-transmitting regions formed on the first light-blocking pad pattern, and a first sub-pattern including a plurality of phase shift regions between the first light-transmitting regions and at an outermost portion of the first mask original plate. A second mask includes a second mask original plate, a second light-blocking pad pattern formed on the second mask original plate, a second main pattern including a plurality of second light-transmitting regions formed on the second light-blocking pad pattern, and a second sub-pattern including a plurality of phase shift regions between the second light-transmitting regions.

Each of the first and second main patterns and the first and second sub-patterns may have a transmittance of approximately 95% to 100%. Light transmitted through the first and second main patterns and light transmitted through the first and second sub-patterns may have a phase difference of approximately 180°. When the first mask and the second mask are aligned for exposure, the first light-transmitting regions of the first main pattern and the second light-transmitting regions of the second main pattern do not overlap each other while the phase shift regions of the first sub-pattern and the phase shift regions of the second sub-pattern do not overlap each other, and the first light-transmitting regions of the first main pattern overlap with the phase shift regions of the second sub-pattern while the second light-transmitting regions of the second main pattern overlap with the phase shift regions of the first sub-pattern.

Line widths of the phase shift regions of the first sub-pattern may be smaller than line widths of the first light-transmitting regions. Line widths of the phase shift regions of the second sub-pattern may be smaller than line widths of the second light-transmitting regions. The phase shift regions may have line widths which are 70% or less of line widths of the light-transmitting regions. The first light-transmitting region and the second light-transmitting region may have approximately equal line widths. Among the phase shift regions of the first sub-pattern, a phase shift region positioned at an outermost portion of the first mask original plate may have a minimum line width.

Embodiments relate to a method of forming a fine mask pattern using a plurality of masks which includes forming a first mask, including forming a first light-blocking pad pattern on a first mask original plate, forming a first main pattern including a first light-transmitting region on the first light-blocking pad pattern, and forming a first sub-pattern including a plurality of phase shift regions at opposite sides of the first light-transmitting region. The method also includes forming a second mask, including forming a second light-blocking pad pattern on a second mask original plate, forming a second main pattern including a second light-transmitting region on the second light-blocking pad pattern, and forming a second sub-pattern including a plurality of phase shift regions at opposite sides of the second light-transmitting region. The method includes aligning and exposing the first and second masks.

Light transmitted through the first and second sub-patterns and light transmitted through the first and second main patterns has a phase difference of approximately 180°. Each of the first and second main patterns and the first and second sub-patterns has transmittance between approximately 95% and 100%.

Line widths of the phase shift regions of the first sub-pattern is smaller than line widths of the first light-transmitting region. Line widths of the phase shift regions of the second sub-pattern are smaller than line widths of the second light-transmitting region. The first light-transmitting region and the second light-transmitting region have approximately equal line widths. Among the phase shift regions of the first sub-pattern, a phase shift region positioned at an outermost portion of the first mask original plate has a minimum line width. The phase shift regions of the first sub-pattern and the phase shift regions of the second sub-pattern have line widths which are 70% or less of line widths of the first light-transmitting region and the second light-transmitting region.

The first and second masks are aligned such that the first light-transmitting region of the first main pattern and the second light-transmitting region of the second main pattern do not overlap each other. The first and second masks are aligned such that the phase shift regions of the first sub-pattern and the phase shift regions of the second sub-pattern do not overlap each other. The first and second masks are aligned such that the first light-transmitting region of the first main pattern overlaps the phase shift regions of the first sub-pattern and the second light-transmitting region of the second main pattern overlaps the phase shift regions of the second sub-pattern.

According to embodiments, it is possible to increase the optical resolution by adding a fine sub-pattern serving as a phase shift mask to a main pattern for forming a pattern of a semiconductor wafer, thereby improving accuracy of line width resolution of the main pattern. In particular, the phase shift regions applied to the fine sub-pattern are formed to have different line widths. Accordingly, it is possible to realize fine patterning due to a double mask in exposure and also to correct an optical proximity effect. That is, since the optical proximity effect is relieved, a double exposure mask formed using two masks according to embodiments can improve resolution. The double exposure mask according to embodiments is effective when patterns formed by exposure are close to each other and also may improve resolution of an isolated pattern.

### DRAWINGS

FIG. 1A illustrates a double exposure mask according to a related technology.

FIG. 1B illustrates two masks for forming the mask of FIG. 1A.

FIG. 1C illustrates a resist pattern formed by the two masks shown in FIG. 1B, including an optical image and an exposure contour image, which are generated using a simulation tool.

Example FIG. 2 illustrates one mask of a double exposure mask according to embodiments.

Example FIG. 3 illustrates the other mask of the double exposure mask according to embodiments.

Example FIG. 4 illustrates a resist pattern image obtained when the mask of example FIG. 2 and the mask of example FIG. 3 are aligned and exposed.

### DESCRIPTION

Example FIG. 2 illustrates one mask of a double exposure mask according to embodiments. Example FIG. 3 illustrates the other mask of the double exposure mask according to embodiments. Example FIG. 4 illustrates a resist pattern image obtained when the mask of example FIG. 2 and the mask of example FIG. 3 are aligned and exposed.

Example FIGS. 2 and 3 illustrate two masks, and example FIG. 4 illustrates a state in which the two masks optically overlap each other. In embodiments, when the mask of example FIG. 2 and the mask of example FIG. 3 overlap each other, the masks are arranged such that main patterns of the respective masks do not overlap each other. That is, when the two masks of example FIGS. 2 and 3 overlap each other, the main patterns of the respective masks are positioned without overlapping each other.

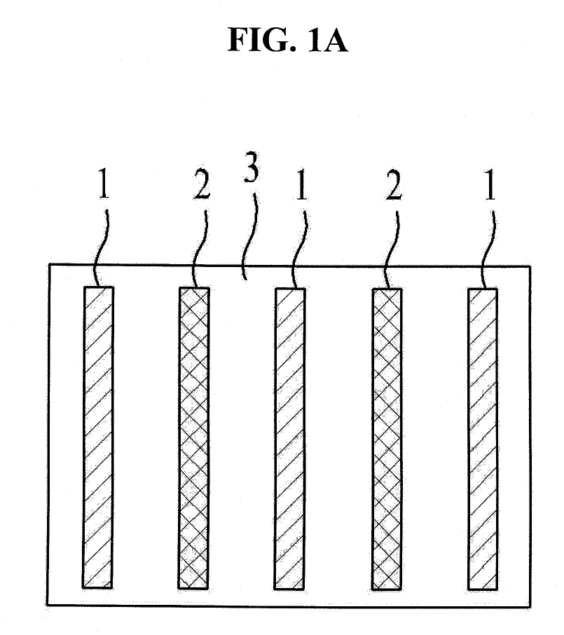

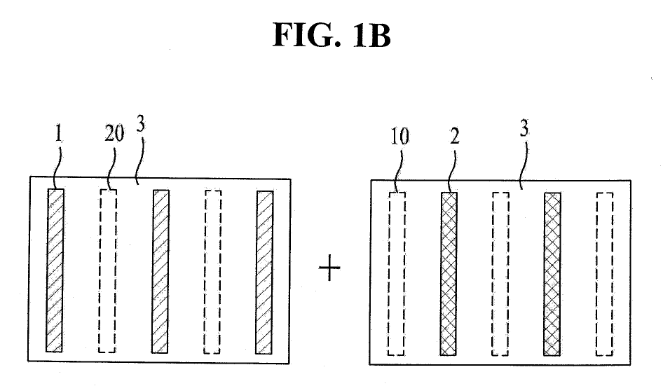

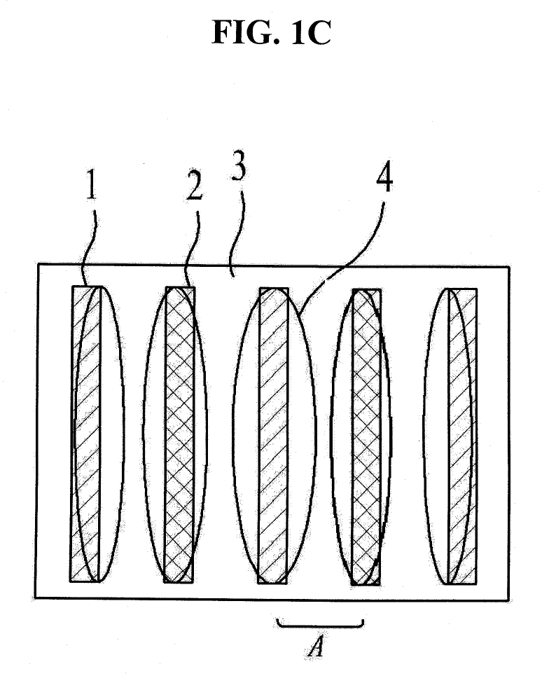

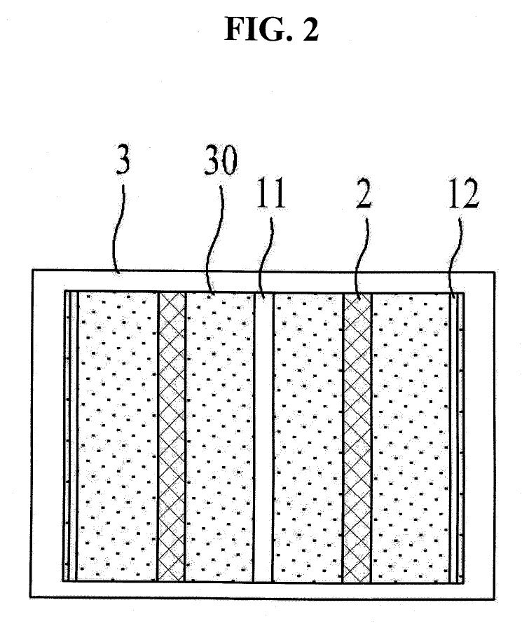

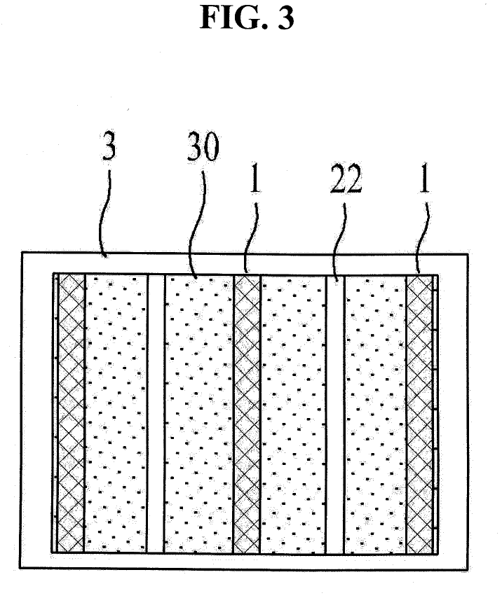

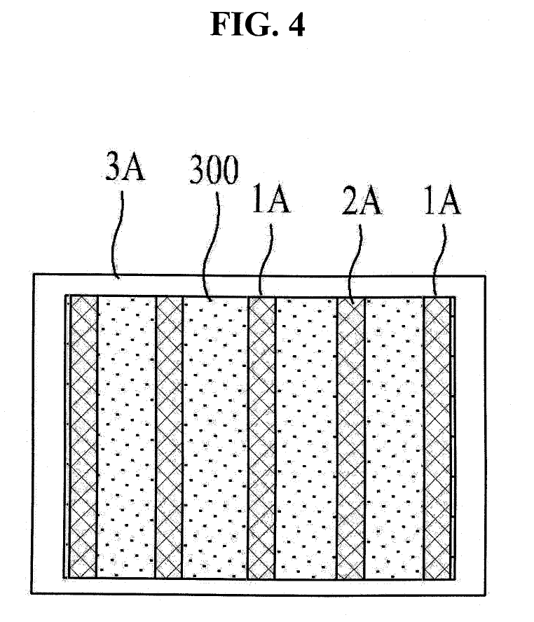

In the following description, the mask of example FIG. 2 is referred to as a first mask and the mask of example FIG. 3 is referred to as a second mask. Further, main patterns 1 and 2 and an original plate 3 of the respective masks have the same reference numerals for comparison with those of FIGS. 1A to 1C.

The first mask shown in example FIG. 2 includes a first mask original plate 3, a first light-blocking pad pattern 30, a first main pattern and a first sub-pattern. The first light-blocking pad pattern 30 is formed on the first mask original plate. In the first mask, the first main pattern and the first sub-pattern are patterned on the first light-blocking pad pattern 30. Further, each of the first main pattern and the first sub-pattern has transmittance of 95 to 100%.

The first main pattern includes a plurality of first light-transmitting regions 2 which are formed to be spaced from each other in a longitudinal direction. The first light-transmitting regions 2 of the first main pattern have the same line width.

The first sub-pattern, which serves as a phase shift pattern, includes a plurality of phase shift regions 11 and 12 which are spaced from each other in a longitudinal direction. Specifically, the phase shift regions 11 and 12 are formed at opposite sides of each of the first light-transmitting regions 2 to enhance resolution of the first light-transmitting regions 2. In other words, the phase shift regions 11 and 12 are formed between the first light-transmitting regions 2 and at an outermost portion of the first mask original plate 3.

As shown in example FIG. 2, the phase shift regions 11 and 12 are formed at the opposite sides of each of the first light-transmitting regions 2, and have different line widths. A maximum line width of the phase shift regions 11 and 12 is smaller than the line width of the first light-transmitting regions 2. For example, the maximum line width of the phase shift regions 11 and 12 has a line width which is 70% or less of the line width of the first light-transmitting regions 2. The first sub-pattern should not be resolved, and exists to compensate the first main pattern. The maximum line width of the phase shift regions 11 and 12 should be smaller than a threshold line width capable being resolved. Thus the phase shift regions have a resolution smaller than a threshold resolution. In particular, the phase shift regions 12 formed at the outermost portion of the first mask original plate 3 have a minimum line width.

A second mask shown in example FIG. 3 also includes a second mask original plate 3, a second light-blocking pad pattern 30, a second main pattern and a second sub-pattern. The second light-blocking pad pattern 30 is formed on the second mask original plate. The second mask original plate 3 of the second mask and the second light-blocking pad pattern 30 have the same reference numerals as those of the first mask for convenience of explanation.

In the second mask, the second main pattern and the second sub-pattern are patterned on the second light-blocking pad pattern 30. Each of the second main pattern and the second sub-pattern has transmittance of 95 to 100% as in the first main pattern and the first sub-pattern. The second main pattern includes a plurality of second light-transmitting regions 1 which are spaced from each other in a longitudinal direction. The second light-transmitting regions 1 of the second main pattern have the same line width.

The second sub-pattern, which serves as a phase shift pattern, includes a plurality of phase shift regions 22 which are spaced from each other in a longitudinal direction. In particular, the phase shift regions 22 are formed at opposite sides or at one side of each of the second light-transmitting regions 1 to enhance resolution of the second light-transmitting regions 1. In other words, the phase shift regions 22 are formed between the second light-transmitting regions 1 and the light-transmitting regions are formed at an outermost portion of the second mask original plate 3.

As shown in example FIG. 3, the phase shift regions 22 are formed at the opposite sides of each of the second light-transmitting regions 1. A maximum line width of the phase shift regions 22 is smaller than the line width of the second light-transmitting regions 1. For example, the maximum line width of the phase shift regions 22 has a line width which is 70% or less of the line width of the second light-transmitting regions 1. The second sub-pattern should not be resolved, and exists only to compensate the second main pattern. The maximum line width of the phase shift regions 22 should be smaller than a threshold line width capable being resolved. That is, the phase shift regions 22 have a resolution smaller than a threshold resolution.

As shown in example FIG. 4, when the first mask of example FIG. 2 and the second mask of example FIG. 3 are aligned and exposed, high-resolution patterns 1A and 2A having the same size are formed on the surface of a resist 300. As the first mask of example FIG. 2 and the second mask of example FIG. 3 are aligned, the first main pattern of the first mask and the second main pattern of the second mask do not overlap each other, and the first sub-pattern of the first mask and the second sub-pattern of the second mask do not overlap each other and are not resolved. That is, the light-transmitting regions of the different masks are aligned without overlapping each other. Further, the phase shift regions of the different masks are aligned without overlapping each other.

When the different masks are aligned for exposure, the pattern regions having different phases overlap each other. That is, the first light-transmitting regions of the first main pattern overlap with the phase shift regions of the second sub-pattern, and the second light-transmitting regions of the second main pattern overlap with the phase shift regions of the first sub-pattern.

For example, when the first and second masks are aligned for exposure, the first and second masks are aligned such that the first main pattern corresponds to the second sub-pattern and the second main pattern corresponds to the first sub-pattern. Accordingly, when the two masks overlap each other, the second sub-pattern of the second mask is positioned at the first main pattern of the first mask, and the first sub-pattern of the first mask is positioned at the second main pattern of the second mask. The two masks of the example FIGS. 2 and 3 may be aligned and exposed in an exposure apparatus. Hereinafter, a procedure for fabricating a fine mask using a plurality of masks will be described based on the above description.

Referring to example FIGS. 2 and 3, in the fabrication of a fine mask according to embodiments, after the first mask of example FIG. 2 and the second mask of example FIG. 3 are formed, the first and second masks are aligned and an exposure process is performed thereon.

The first mask may be formed as follows. The first light-blocking pad pattern 30 is formed on the first mask original plate 3. Then, the first main pattern including at least one first light-transmitting region 2 is formed on the first light-blocking pad pattern. The first light-transmitting regions 2 may have the same line width and may be spaced from each other in a longitudinal direction.

The first sub-pattern including the phase shift regions 11 and 12 having a line width smaller than the line width of the first light-transmitting regions 2 may be formed at the opposite sides of the first light-transmitting regions of the first main pattern. The phase shift regions 11 and 12, which are formed at the opposite sides of the first light-transmitting regions 2, may have different line widths and may be spaced in parallel from the first light-transmitting regions 2 in a longitudinal direction.

The phase shift regions 11 and 12 are formed between the first light-transmitting regions 2 and at the outermost portion of the first mask original plate 3 to enhance the resolution of the first main pattern. The phase shift regions 12 positioned at the outermost portion of the first mask original plate 3 may be formed to have a minimum line width. The phase shift region 11 positioned between the first light-transmitting regions 2 may be formed to have a line width larger than the minimum line width. However, the phase shift regions 11 and 12 have a line width smaller than the line width of the first light-transmitting regions 2. For example, a maximum line width of the phase shift regions 11 and 12 may have a line width which is 70% or less of the line width of the first light-transmitting regions 2.

The second mask may be formed as follows. The second light-blocking pad pattern 30 may be formed on the second mask original plate 3. The second main pattern including at least one second light-transmitting region 1 may be formed on the second light-blocking pad pattern. The second light-transmitting regions 1 may have the same line width and may be spaced from each other in a longitudinal direction. The second sub-pattern including the phase shift regions 22 may have a line width smaller than the line width of the second light-transmitting regions 1. The second sub-pattern may be formed at the opposite sides or at one side of the second light-transmitting regions of the second main pattern.

The phase shift regions 22, which may be formed at the opposite sides of the second light-transmitting regions 1, may have the same line width and may be spaced in parallel from the second light-transmitting regions 1 in a longitudinal direction. The phase shift regions 22 may be formed at opposite sides or at one side of the second light-transmitting regions 1 to enhance the resolution of the second main pattern. The phase shift regions 22 may be formed to have a line width smaller than the line width of the second light-transmitting regions 1. For example, a maximum line width of the phase shift regions 22 may be 70% or less of the line width of the second light-transmitting regions 1.

In the first and second masks, the light-transmitting regions of the main pattern and the phase shift regions of the sub-pattern are formed to have a phase difference of approximately 180°. That is, the phase shift regions transmit incident light therethrough while reversing the phase of the incident light. Accordingly, light transmitted through the phase shift regions and light transmitted through the light-transmitting regions have a phase difference of 180°. For example, when light transmitted through the light-transmitting regions of the main pattern has a phase of 0°, light transmitted through the phase shift regions of the sub-pattern has a phase of 180°.

Then, when the first and second masks are aligned for exposure, the first and second masks are aligned such that the first main pattern corresponds to the second sub-pattern and the second main pattern corresponds to the first sub-pattern. In other words, the first and second masks are aligned such that the first light-transmitting regions 2 of the first main pattern and the second light-transmitting regions 1 of the second main pattern do not overlap each other. The first and second masks are aligned such that the phase shift regions 11 and 12 of the first sub-pattern and the phase shift regions 22 of the second sub-pattern do not overlap each other.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a first mask, including forming a first light-blocking pad pattern on a first mask original plate, forming a first main pattern including a first light-transmitting region on the first light-blocking pad pattern, and forming a first sub-pattern including a plurality of phase shift regions at opposite sides of the first light-transmitting region;
forming a second mask, including forming a second light-blocking pad pattern on a second mask original plate, forming a second main pattern including a second light-transmitting region on the second light-blocking pad pattern, and forming a second sub-pattern including a plurality of phase shift regions at opposite sides of the second light-transmitting region; and
aligning and exposing the first and second masks.

2. The method of claim 1, wherein light transmitted through the first and second sub-patterns and light transmitted through the first and second main patterns has a phase difference of approximately 180°.

3. The method of claim 1, wherein each of the first and second main patterns and the first and second sub-patterns has transmittance between approximately 95% and 100%.

4. The method of claim 1, wherein line widths of the phase shift regions of the first sub-pattern is smaller than line widths of the first light-transmitting region.

5. The method of claim 1, wherein line widths of the phase shift regions of the second sub-pattern are smaller than line widths of the second light-transmitting region.

6. The method of claim 1, wherein the first light-transmitting region and the second light-transmitting region have approximately equal line widths.

7. The method of claim 1, wherein among the phase shift regions of the first sub-pattern, a phase shift region positioned at an outermost portion of the first mask original plate has a minimum line width.

8. The method of claim 1, wherein the phase shift regions of the first sub-pattern and the phase shift regions of the second sub-pattern have line widths which are 70% or less of line widths of the first light-transmitting region and the second light-transmitting region.

9. The method of claim 1, wherein the first and second masks are aligned such that the first light-transmitting region of the first main pattern and the second light-transmitting region of the second main pattern do not overlap each other.

10. The method of claim 1, wherein the first and second masks are aligned such that the phase shift regions of the first sub-pattern and the phase shift regions of the second sub-pattern do not overlap each other.

11. The method of claim 1, wherein the first and second masks are aligned such that the first light-transmitting region of the first main pattern overlaps the phase shift regions of the first sub-pattern and the second light-transmitting region of the second main pattern overlaps the phase shift regions of the second sub-pattern.

12. An apparatus comprising:
a first mask, including a first mask original plate, a first light-blocking pad pattern formed on the first mask original plate, a first main pattern including a plurality of first light-transmitting regions formed on the first light-blocking pad pattern, and a first sub-pattern including a plurality of phase shift regions between the first light-transmitting regions and at an outermost portion of the first mask original plate; and
a second mask, including a second mask original plate, a second light-blocking pad pattern formed on the second mask original plate, a second main pattern including a plurality of second light-transmitting regions formed on the second light-blocking pad pattern, and a second sub-pattern including a plurality of phase shift regions between the second light-transmitting regions.

13. The apparatus of claim 12, wherein light transmitted through the first and second main patterns and light transmitted through the first and second sub-patterns has a phase difference of approximately 180°.

14. The apparatus of claim 12, wherein each of the first and second main patterns and the first and second sub-patterns has a transmittance of approximately 95% to 100%.

15. The apparatus of claim 12, wherein when the first mask and the second mask are aligned for exposure, the first light-transmitting regions of the first main pattern and the second light-transmitting regions of the second main pattern do not overlap each other while the phase shift regions of the first sub-pattern and the phase shift regions of the second sub-pattern do not overlap each other, and the first light-transmitting regions of the first main pattern overlap with the phase shift regions of the second sub-pattern while the second light-transmitting regions of the second main pattern overlap with the phase shift regions of the first sub-pattern.

16. The apparatus of claim 12, wherein line widths of the phase shift regions of the first sub-pattern are smaller than line widths of the first light-transmitting regions.

17. The apparatus of claim 12, wherein line widths of the phase shift regions of the second sub-pattern is smaller than line widths of the second light-transmitting regions.

18. The apparatus of claim 12, wherein the phase shift regions have line widths which are 70% or less of line widths of the light-transmitting regions.

19. The apparatus of claim 12, wherein the first light-transmitting region and the second light-transmitting region have approximately equal line widths.

20. The apparatus of claim 12, wherein among the phase shift regions of the first sub-pattern, a phase shift region positioned at an outermost portion of the first mask original plate has a minimum line width.
